(19) United States
(12) Patent Application Publication
(10) Pub. No.: US 2022/0278655 A1
(43) Pub. Date: Sep. 1, 2022

(54) LOW NOISE AMPLIFIER AND RECEPTION CIRCUIT

(71) Applicant: LAPIS Technology Co., Ltd., Yokohama-shi (JP)

(72) Inventor: Toru YOSHIOKA, Yokohama-shi (JP)

(73) Assignee: LAPIS Technology Co., Ltd., Yokohama-shi (JP)

(21) Appl. No.: 17/681,117

(22) Filed: Feb. 25, 2022

(30) Foreign Application Priority Data
Feb. 26, 2021 (JP) 2021-031040

(51) Int. Cl. H03F 3/193

(52) U.S. Cl. CPC H03F 3/193; H03F 2200/294; H03F 2200/222; H03F 1/565

(57) ABSTRACT

A low noise amplifier includes a transistor that amplifies and outputs inputted signals, a buffer that propagates outputs of the transistor to a subsequent circuit, a variable current source that supplies a bias current to the transistor, and a variable resistor connected between a gate terminal of the transistor and a terminal of the transistor to which the variable current source is connected, wherein in a case in which the inputted signals do not pass through the low noise amplifier, the buffer blocks outputs of the transistor, and settings of the variable current source and the variable resistor differ from settings in a case in which the inputted signals pass through the low noise amplifier.

### CROSS-REFERENCE TO RELATED APPLICATION

This application is based on and claims priority under 35 USC 119 from Japanese Patent Application No. 2021-031040 filed on Feb. 26, 2021, the disclosure of which is incorporated by reference herein.

### BACKGROUND

### Technical Field

The present disclosure relates to a low noise amplifier and a reception circuit.

### Related Art

Currently, various wireless communications devices are manufactured that employ Bluetooth (registered trademark) in the 2.4 GHz band, wireless local area networks (LAN) in the 2.4 GHz and 5 GHz bands, portable telephony communication networks and the like. Low noise amplifiers (LNA) are used for amplifying received signals in these wireless communications devices.

However, when an electromagnetic wave strength of received electromagnetic waves is large, a signal strength inputted to a low noise amplifier is strong, the amplified signal saturates, and distortion characteristics decline. Accordingly, a technology has been proposed that, when an electromagnetic wave strength is large, bypasses the amplifier and provides the inputted signal to a subsequent stage without amplification. For example, Japanese Patent Application Laid-Open (JP-A) No. 2009-290411 discloses a low noise amplifier with a bypass function that, when in a bypass mode, adjusts an input impedance of a bypass path with a switch and a capacitor.

However, because the capacitor is formed for the low noise amplifier disclosed in JP-A No. 2009-290411 to adjust the input impedance of the bypass path with the switch and the capacitor when in the bypass mode, circuit size is increased.

### SUMMARY

A low noise amplifier according to an aspect of the present disclosure includes a transistor that amplifies and outputs inputted signals, a buffer that propagates outputs of the transistor to a subsequent circuit, a variable current source that supplies a bias current to the transistor, and a variable resistor connected between a gate terminal of the transistor and a terminal of the transistor to which the variable current source is connected, wherein, in a case in which the inputted signals do not pass through the low noise amplifier, the buffer blocks outputs of the transistor, and settings of the variable current source and the variable resistor differ from settings in a case in which the inputted signals pass through the low noise amplifier.

### BRIEF DESCRIPTION OF THE DRAWINGS

Exemplary embodiments of the present disclosure will be described in detail based on the following figures, wherein:

FIG. 1 is a diagram showing schematic structures of a reception circuit according to an exemplary embodiment of the present disclosure.

FIG. 2 is a diagram showing a circuit structure example of an amplification section according to the exemplary embodiment.

FIG. 3 is a diagram showing a circuit structure example of an LNA according to the exemplary embodiment.

FIG. 4 is a diagram showing schematic structures of a reception circuit according to a related technology.

FIG. 5 is a diagram showing a circuit structure example of an amplification section according to the related technology.

FIG. 6A is a diagram describing operation of the amplification section according to the related technology.

FIG. 6B is a diagram describing operation of the amplification section according to the related technology.

### DETAILED DESCRIPTION

Below, an example of an embodiment of the present disclosure is described with reference to the drawings. In the drawings, the same reference symbols are assigned to structural elements and portions that are the same or equivalent. Proportional dimensions in the drawings are exaggerated to facilitate understanding and may be different from actual proportions.

—Related Technology—

Before the example of an embodiment of the present disclosure is described, a conventional technology that is a precursor of this exemplary embodiment is described.

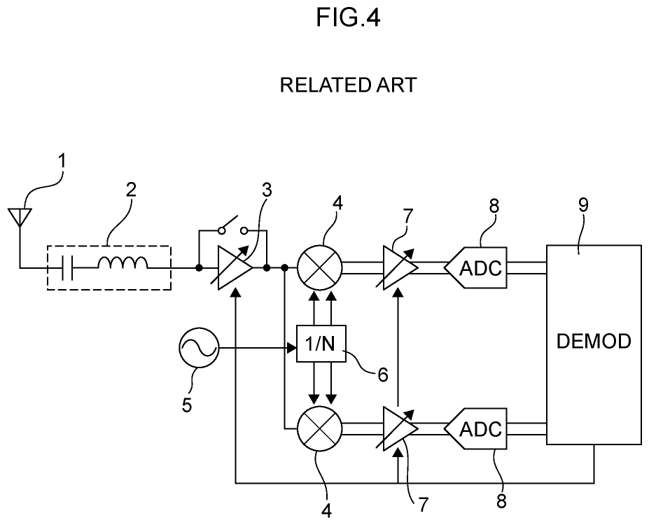

FIG. 4 is a diagram showing schematic structures of a reception circuit according to the related technology. The reception circuit shown in FIG. 4 is employed with, for example, Bluetooth in the 2.4 GHz band, a wireless LAN in the 2.4 GHz or 5 GHz band, a portable telephony communication network or the like.

The reception circuit shown in FIG. 4 is a circuit that amplifies a modulated signal inputted through an antenna, applies frequency modulation processing or the like, and demodulates information carried by the signal. The reception circuit in FIG. 4 is structured by an antenna 1, a matching circuit 2, an amplification section 3, a mixer 4, a local oscillator 5, a frequency divider 6, an analog amplifier 7, an analog-to-digital converter (ADC) 8 and a demodulator (DEMOD) 9.

The antenna 1 receives weak, high-frequency electromagnetic waves transmitted through the air. The antenna 1 typically has an impedance of 50Ω.

The matching circuit 2 is formed of a coil and a capacitor, and converts an input impedance of the reception circuit as seen by the antenna 1. The impedance of the matching circuit 2 matches at around 50Ω, thus preventing signal reflections to the antenna 1.

The amplification section 3 amplifies weak, high-frequency wave signals from the antenna 1 with low noise. The amplification section 3 features a function for altering gain in accordance with signal strength. Specifically, when the signal strength is large, the amplification section 3 operates in a bypass mode to propagate signals directly from the antenna 1 to the mixer 4.

The mixer 4 converts high-frequency signals outputted from the amplification section 3 to intermediate frequency signals. The local oscillator 5 generates a local signal for frequency conversion at the mixer 4, and outputs the local signal to the frequency divider 6. The frequency divider 6 divides the output signal from the local oscillator 5 to a suitable frequency and generates orthogonal signals. Switching operations of the mixer 4 are implemented by output signals from the frequency divider 6. Thus, the intermediate frequency is generated at the mixer 4. Image components may be eliminated by the demodulator 9 with the orthogonal signals generated by the frequency divider 6.

The analog amplifier 7 amplifies signals outputted from the mixer 4. The analog amplifier 7 includes a function for altering gain in accordance with a signal strength of signals demodulated by the demodulator 9. The ADC 8 converts signals outputted from the analog amplifier 7 to digital signals. The ADC 8 saturates when large signals are inputted, which hinders conversion operations and demodulation. Accordingly, the gains of the amplification section 3 and the analog amplifier 7 are altered such that the ADC 8 does not saturate.

The demodulator 9 demodulates the digital modulated signals outputted from the ADC 8 and reads information from the demodulated signals. The demodulator 9 includes a function for measuring signal strength. Hence, the demodulator 9 adjusts the gains of the amplification section 3 and the analog amplifier 7 in accordance with signal strengths.

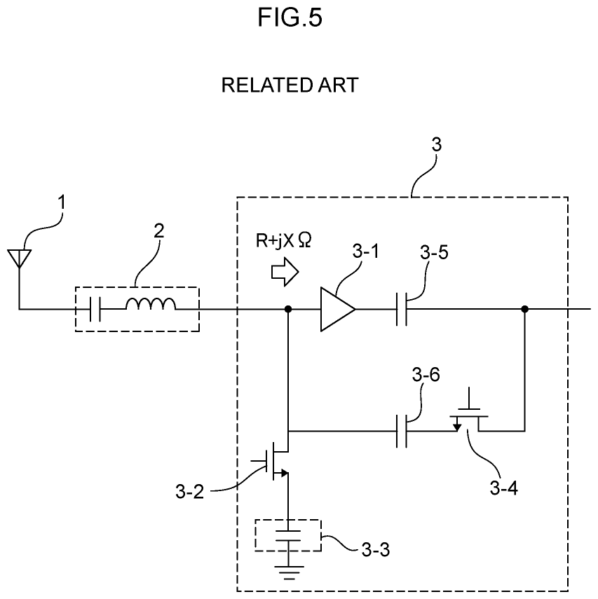

FIG. 5 is a diagram showing a circuit structure example of the amplification section 3. The amplification section 3 is formed of an LNA main body, which amplifies signals when in an amplification mode, and a path, which is parallel with the LNA and propagates signals when in the bypass mode. The amplification section 3 is put into the bypass mode when a signal strength measured by the demodulator 9 is greater than a predetermined threshold. During the bypass mode, input matching must be maintained with constants of the matching circuit 2 remaining fixed. The amplification section 3 is provided with an LNA 3-1, NMOS switches 3-2 and 3-4, a matching circuit 3-3, and capacitors 3-5 and 3-6. Circuit structures of the amplification section 3 are described below.

The LNA 3-1 amplifies signals from the antenna 1. The input impedance of the LNA 3-1 when in the amplification mode is expressed by R+jX (Ω), in which R represents a resistance component, j represents the imaginary unit and X represents a reactance component. When in the bypass mode, when the NMOS switch 3-4 is in an on state under control from the demodulator 9, the LNA 3-1 is in an off state. When the LNA 3-1 is in the off state, the LNA 3-1 does not amplify and does not propagate signals from the antenna 1.

The NMOS switch 3-2 is structured by an NMOS transistor and is switched on and off under control from the demodulator 9. When in the bypass mode, the NMOS switch 3-2 is turned on under control from the demodulator 9, and when in the amplification mode, the NMOS switch 3-2 is turned off under control from the demodulator 9.

When in the bypass mode, the matching circuit 3-3 adjusts the input impedance combined with the NMOS switch 3-2 to R+jX. In FIG. 5, a capacitor is formed to serve as the matching circuit 3-3.

The NMOS switch 3-4 is structured by an NMOS transistor and is switched on and off under control from the demodulator 9. When in the bypass mode, the NMOS switch 3-4 is turned on under control from the demodulator 9, and when in the amplification mode, the NMOS switch 3-4 is turned off under control from the demodulator 9.

The capacitors 3-5 and 3-6 are provided to block DC components.

Operation of the amplification section 3 is now described.

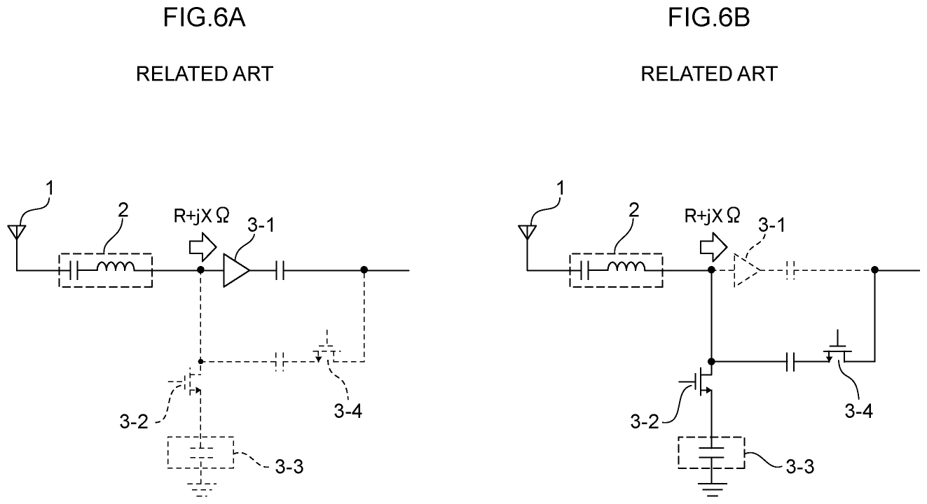

FIG. 6A and FIG. 6B are diagrams describing operation of the amplification section 3. FIG. 6A is a diagram describing operation of the amplification section 3 when in the amplification mode, and FIG. 6B is a diagram describing operation of the amplification section 3 when in the bypass mode.

As shown in FIG. 6A, when in the amplification mode, the NMOS switches 3-2 and 3-4 of the amplification section 3 are turned off under control from the demodulator 9. Thus, signals from the antenna 1 are amplified by the LNA 3-1 and outputted to the subsequent mixer 4.

In contrast, when in the bypass mode, the NMOS switches 3-2 and 3-4 of the amplification section 3 are turned on under control from the demodulator 9. Thus, signals from the antenna 1 are outputted to the subsequent mixer 4 without being amplified by the LNA 3-1. When in the bypass mode, the input impedance is adjusted to R+jX (Ω) by the NMOS switch 3-2 and matching circuit 3-3.

However, the matching circuit 3-3 is added to the reception circuit with the structure described above in order to match the impedance when in the bypass mode. The matching circuit 3-3 is a capacitor; an increase in area of the circuit due to the formation of this capacitor is disadvantageous. Specifically, depending on a number of passive components that are required, a large region is required within an LSI circuit, leading to an increase in costs.

Accordingly, to solve the problem described above, the inventors of the present disclosure have conducted diligent investigations into a technology for a low noise amplifier and reception circuit that may realize a bypass function without increasing circuit size. As a result, the inventors of the present disclosure have arrived at a proposal for a low noise amplifier and reception circuit that may realize a bypass function without a capacitor being formed, as described below.

### Exemplary Embodiment

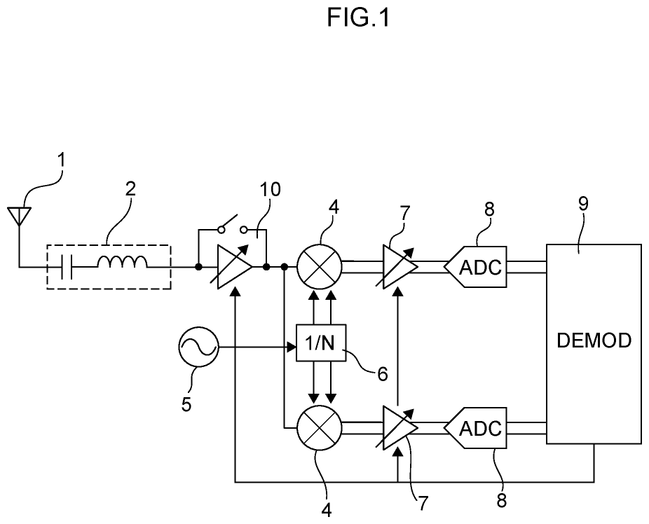

FIG. 1 is a diagram showing a schematic example of a reception circuit according to the exemplary embodiment of the present disclosure. The reception circuit shown in FIG. 1 is employed with, for example, Bluetooth in the 2.4 GHz band, a wireless LAN in the 2.4 GHz or 5 GHz band, a portable telephony communication network or the like.

The reception circuit shown in FIG. 1 is a circuit that amplifies a modulated signal inputted through an antenna, applies frequency modulation processing or the like, and demodulates information carried by the signal. The reception circuit in FIG. 1 is structured by the antenna 1, the matching circuit 2, an amplification section 10, the mixer 4, the local oscillator 5, the frequency divider 6, the analog amplifier 7, the analog-to-digital converter (ADC) 8 and the demodulator (DEMOD) 9.

Structures other than the amplification section 10 are similar to the reception circuit shown in FIG. 4. Therefore, detailed descriptions thereof are not given here. Now, the amplification section 10 is described.

The amplification section 10 amplifies weak, high-frequency wave signals from the antenna 1 with low noise. The amplification section 10 features a function for altering gain in accordance with signal strength. Specifically, when the signal strength is large, the amplification section 10 operates in the bypass mode to propagate signals directly from the antenna 1 to the mixer 4. The amplification section 10 differs from the amplification section 3 according to the related technology shown in FIG. 4 in that no capacitor is formed for matching the impedance when in the bypass mode.

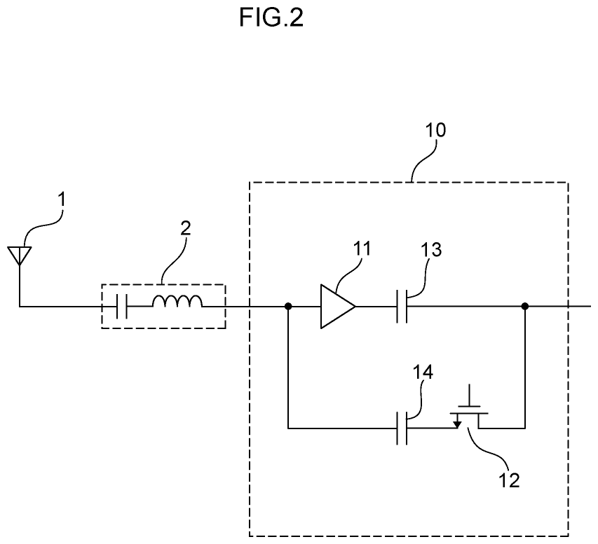

FIG. 2 is a diagram showing detailed structure of the amplification section 10. The amplification section 10 is structured by a low noise amplifier (LNA) 11, an NMOS switch 12, and capacitors 13 and 14.

The LNA 11 amplifies signals from the antenna 1. The LNA 11 constitutes a resistance feedback-type LNA. An input impedance of the LNA 11 when in the amplification mode is expressed by R+jX. When the NMOS switch 12 is turned on under control from the demodulator 9 during the bypass mode, the LNA 11 is put into an off state. When the LNA 11 is in the off state, the LNA 11 does not amplify and does not propagate signals from the antenna 1.

The NMOS switch 12 is structured by an NMOS transistor and is switched on and off under control from the demodulator 9. When in the bypass mode, the NMOS switch 12 is turned on under control from the demodulator 9, and when in the amplification mode, the NMOS switch 12 is turned off under control from the demodulator 9.

The capacitors 13 and 14 are provided to block DC components.

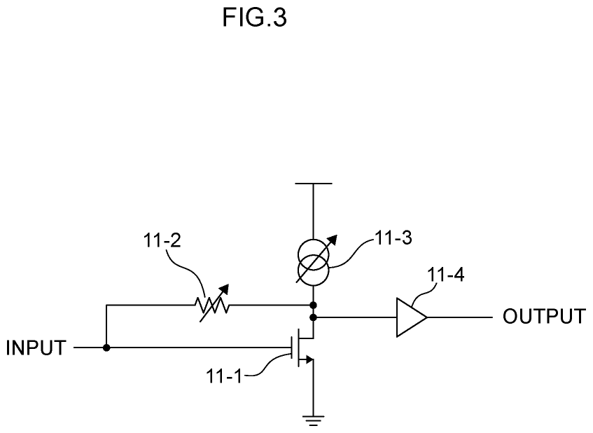

Detailed circuit structure of the LNA 11 is described. FIG. 3 is a diagram showing a detailed circuit structure example of the LNA 11.

The LNA 11 is structured by an NMOS transistor 11-1, a variable resistor 11-2, a variable current source 11-3 and a buffer 11-4.

The NMOS transistor 11-1 is an active component structuring the LNA 11. The NMOS transistor 11-1 amplifies and outputs input signals.

The variable resistor 11-2 is a resistor structuring the LNA 11. The resistance value of the variable resistor 11-2 is adjusted by settings of the variable resistor 11-2. Thus, the gain and input impedance of the LNA 11 may be adjusted. In the present exemplary embodiment, the gain and input impedance of the LNA 11 may be adjusted by changing the resistance value of the variable resistor 11-2 between the amplification mode and the bypass mode.

The variable current source 11-3 is a current source structuring the LNA 11. The current value of a bias current supplied from the variable current source 11-3 to the NMOS transistor 11-1 is adjusted by settings of the variable current source 11-3. Thus, the gain and input impedance of the LNA 11 may be adjusted. In the present exemplary embodiment, the current value of the bias current supplied from the variable current source 11-3 to the NMOS transistor 11-1 is changed by changing a resistance value between the amplification mode and the bypass mode.

When in the amplification mode, the buffer 11-4 propagates signals amplified by the NMOS transistor 11-1 to the mixer 4. When in the bypass mode, the buffer 11-4 is in an off state. Thus, signals amplified by the NMOS transistor 11-1 are blocked, preventing propagation of signals from the LNA 11 to the mixer 4.

In accordance with a result of comparison of a signal strength measured by the demodulator 9 with a predetermined threshold, the reception circuit of FIG. 1 determines whether to operate in the amplification mode or operate in the bypass mode. The amplification section 10 operates in either the amplification mode or the bypass mode in accordance with signals from the demodulator 9. When a signal strength measured by the demodulator 9 is less than the predetermined threshold, the reception circuit of FIG. 1 operates in the amplification mode. When a signal strength measured by the demodulator 9 is at least the predetermined threshold, the reception circuit of FIG. 1 operates in the bypass mode. The LNA 11 according to the present exemplary embodiment changes the resistance value of the variable resistor 11-2 and the current value supplied by the variable current source 11-3 between the amplification mode and the bypass mode. In addition, when the LNA 11 according to the present exemplary embodiment is in the amplification mode, the buffer 11-4 is in the on state, and when the LNA 11 is in the bypass mode, the buffer 11-4 is in the off state.

That is, because the LNA 11 according to the present exemplary embodiment changes the resistance value of the variable resistor 11-2 and the current value supplied by the variable current source 11-3 between the amplification mode and the bypass mode, the input impedance may be adjusted to R+jX both when in the amplification mode and when in the bypass mode.

Operation of the LNA 11 is now described. When in the amplification mode, the LNA 11 amplifies signals from the antenna 1 and outputs the signals to the subsequent mixer 4. When in the bypass mode, the LNA 11 operates the NMOS transistor 11-1, the variable resistor 11-2 and the variable current source 11-3 such that the LNA 11 is seen as a load of R+jX. When in the bypass mode, the buffer 11-4 blocks signals. The LNA 11 may operate as usual during the bypass mode but, because there is no need to amplify the signals, the amplified signals are blocked by the buffer 11-4 and power consumption may be lowered.

The input impedance of the LNA 11 is now described. If the transconductance of the NMOS transistor 11-1 is represented by gm, the current from the variable current source 11-3 is represented by Id, and the NMOS transistor 11-1 operates in saturation mode, the following expression (1) applies. In expression (1), Cₒₓ represents an oxide layer capacitance of the NMOS transistor 11-1, W represents a channel width of the NMOS transistor 11-1, L represents a channel length of the NMOS transistor 11-1, and μ represents electron mobility.

$$gm \approx \sqrt{2 μ {C}_{ox} \frac{W}{L} Id} \qquad ( 1 )$$

If the resistance value of the variable resistor 11-2 is represented by Rf and an output resistance of the NMOS transistor 11-1 is represented by ro, the resistance R in the input impedance of the LNA 11 which is a resistance feedback-type LNA is given by the following expression (2).

$$R \approx \frac{1}{gm} + \frac{Rf}{gm \cdot ro} \qquad ( 2 )$$

The reactance X in the input impedance of the LNA 11 is caused by parasitic capacitances between pads and wiring of the LSI circuit and the NMOS transistor 11-1, and suchlike.

According to expressions (1) and (2), the input impedance of the LNA 11 may be adjusted to be constant by the current value and resistance value of the LNA 11. When the LNA 11 is in the bypass mode, the resistance value according to the variable resistor 11-2 and the current value of the variable current source 11-3 are reduced. Thus, the input impedance of the LNA 11 may be kept substantially consistent with the amplification mode. During the bypass mode of the LNA 11, because the current value of the variable current source 11-3 is smaller and signals are blocked by the buffer 11-4, power consumption may be lowered compared to the amplification mode. Furthermore, the LNA 11 according to the present exemplary embodiment does not require the matching circuit 3-3 that is required in the related technology. Thus, an increase in circuit area may be prevented.

In the exemplary embodiment described above, the demodulator 9 adjusts the gains of the amplification section 10 and the analog amplifier 7, but the present disclosure is not limited by this example. A circuit for adjusting the gains of the amplification section 10 and the analog amplifier 7 may be provided separately from the demodulator 9.

An object of the present disclosure is to provide a low noise amplifier and reception circuit that may realize a bypass function without increasing circuit size.

A low noise amplifier according to a first aspect of the present disclosure includes a transistor that amplifies and outputs inputted signals, a buffer that propagates outputs of the transistor to a subsequent circuit, a variable current source that supplies a bias current to the transistor, and a variable resistor connected between a gate terminal of the transistor and a terminal of the transistor to which the variable current source is connected, wherein, in a case in which the inputted signals do not pass through the low noise amplifier, the buffer blocks outputs of the transistor, and settings of the variable current source and the variable resistor differ from settings in a case in which the inputted signals pass through the low noise amplifier.

A low noise amplifier according to a second aspect of the present disclosure is the first aspect of the present disclosure, wherein the settings of the variable current source and the variable resistor are changed in accordance with a result of comparison of a signal strength based on outputs of the transistor with a predetermined threshold.

A reception circuit according to a third aspect of the present disclosure includes a low noise amplifier that includes a transistor that amplifies and outputs inputted signals, a buffer that propagates outputs of the transistor to a subsequent circuit, a variable current source that supplies a bias current to the transistor, and a variable resistor connected between a gate terminal of the transistor and a terminal of the transistor to which the variable current source is connected; a bypass circuit that bypasses the low noise amplifier; and a determination circuit that determines a signal strength based on outputs of the low noise amplifier, wherein, in a case in which, based on a determination result of the determination circuit, the inputted signals pass through the bypass circuit without passing through the low noise amplifier, the buffer blocks outputs of the transistor, and settings of the variable current source and the variable resistor differ from settings in a case in which the inputted signals pass through the low noise amplifier.

A reception circuit according to a fourth aspect of the present disclosure further includes a conversion circuit that converts outputs of the low noise amplifier from analog signals to digital signals and outputs the digital signals to the determination circuit, wherein the determination circuit determines a signal strength of the digital signals.

According to the present disclosure, input impedance of a bypass circuit may be adjusted by changing settings of a variable current source and a variable resistor between in a case in which signals pass through the low noise amplifier and in a case in which signals do not pass through the low noise amplifier. According to the present disclosure, because a capacitor is not formed, a low noise amplifier and reception circuit may be provided that may realize a bypass function without increasing circuit size.

What is claimed is:

1. A low noise amplifier comprising:
a transistor that amplifies and outputs inputted signals;
a buffer that propagates outputs of the transistor to a subsequent circuit;
a variable current source that supplies a bias current to the transistor; and
a variable resistor connected between a gate terminal of the transistor and a terminal of the transistor to which the variable current source is connected,
wherein, in a case in which the inputted signals do not pass through the low noise amplifier, the buffer blocks outputs of the transistor, and settings of the variable current source and the variable resistor differ from settings in a case in which the inputted signals pass through the low noise amplifier.

2. The low noise amplifier according to claim 1, wherein the settings of the variable current source and the variable resistor are changed in accordance with a result of comparison of a signal strength based on outputs of the transistor with a predetermined threshold.

3. A reception circuit comprising:
a low noise amplifier including:
a transistor that amplifies and outputs inputted signals,
a buffer that propagates outputs of the transistor to a subsequent circuit,
a variable current source that supplies a bias current to the transistor, and
a variable resistor connected between a gate terminal of the transistor and a terminal of the transistor to which the variable current source is connected;
a bypass circuit that bypasses the low noise amplifier; and
a determination circuit that determines a signal strength based on outputs of the low noise amplifier,
wherein, in a case in which, based on a determination result of the determination circuit, the inputted signals pass through the bypass circuit without passing through the low noise amplifier, the buffer blocks outputs of the transistor, and settings of the variable current source and the variable resistor differ from settings in a case in which the inputted signals pass through the low noise amplifier.

4. The reception circuit according to claim 3, further comprising a conversion circuit that converts outputs of the low noise amplifier from analog signals to digital signals and outputs the digital signals to the determination circuit,
wherein the determination circuit determines a signal strength of the digital signals.
